(19) United States
(12) Patent Application Publication
(10) Pub. No.: US 2025/0323212 A1
(43) Pub. Date: Oct. 16, 2025

(54) SYSTEMS AND METHODS FOR STACK CONSTRUCTION OF A SEMICONDUCTOR DEVICE HAVING REDISTRIBUTION LAYERS IN A SILICON CARRIER

(71) Applicant: Advanced Micro Devices, Inc., Santa Clara, CA (US)

(72) Inventors: Arsalan Alam, Austin, TX (US); Anadi Srivastava, Austin, TX (US); Chandra Sekhar Mandalapu, Fort Collins, CO (US); Chintan Buch, Santa Clara, CA (US); Liwei Wang, Santa Clara, CA (US); Raja Swaminathan, Austin, TX (US)

(73) Assignee: Advanced Micro Devices, Inc., Santa Clara, CA (US)

(21) Appl. No.: 18/194,347

(22) Filed: Mar. 31, 2023

(51) Int. Cl. H01L 25/065; H01L 23/00; H01L 23/538; H01L 25/00

(52) U.S. Cl. CPC H01L 25/0652; H01L 23/5383; H01L 24/08; H01L 24/80; H01L 25/50; H01L 2224/08145; H01L 2224/08225; H01L 2224/80895; H01L 2224/80896

(57) ABSTRACT

The disclosed semiconductor device can include a plurality of stacked circuit dies and a carrier attached to the plurality of stacked circuit dies. A plurality of redistribution layers in the carrier can provide lateral communication for one or more circuit dies of the plurality of stacked circuit dies. Various other methods, systems, and computer-readable media are also disclosed.

### BACKGROUND

Today's packaging methodologies can include multiple dies inside a same package. For example, multiple chips can be arranged in a planar or stacked configuration with an interposer for communication. However, the cost of an interposer is relatively high, which limits packages that include interposers to high-end applications.

In 3D structure, an interposer and dies can be stacked one above another. Dies interact among each other with through-silicon vias (TSVs). TSV is a high performance interconnect made of a pillar-like structure with copper, tungsten, or poly through silicon that provides electrical interconnects through a silicon die or through-wafer.

Silicon bridge technology is an alternative solution to a silicon interposer for heterogeneous integration (e.g., putting multiple and different chips in the same package). Silicon bridge technology provides a similar bandwidth to that provided with an interposer, but at lower cost. Silicon bridge technology uses silicon in the areas where two dies are connected together. Silicon bridge technology yields a lower cost than an interposer.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a flow diagram of an example method for stack construction of a semiconductor device having redistribution layers in a silicon carrier.

FIG. 2 is a block diagram illustrating example semiconductor devices, including an example semiconductor device of chip-on-reconstituted-wafer stack construction and another example semiconductor device also of chip-on-reconstituted-wafer stack construction and having redistribution layers in a silicon carrier that provide lateral communication between two or more circuit dies.

FIG. 3 is a block diagram illustrating example semiconductor devices, including an example semiconductor device of chip-on-reconstituted wafer stack construction that includes a silicon bridge die and another example semiconductor device also of chip-on-reconstituted wafer stack construction and having, instead of a silicon bridge die, redistribution layers in a silicon carrier that provide lateral communication between two or more circuit dies.

FIG. 4 is a block diagram illustrating example semiconductor devices, including an example semiconductor device of chip-on-wafer stack construction and another example semiconductor device also of chip-on-wafer stack construction and having redistribution layers in a silicon carrier that provide lateral communication between two or more circuit dies.

FIG. 5 is a block diagram illustrating an example semiconductor device having N-tier stacked circuit dies and redistribution layers in a silicon carrier that provide lateral communication between two or more circuit dies.

FIG. 6 is a block diagram illustrating initial stages of stacked construction of a semiconductor device having redistribution layers in a silicon carrier.

FIG. 7 is a block diagram illustrating terminal stages of stacked construction of a semiconductor device having redistribution layers in a silicon carrier.

FIG. 8 is a block diagram illustrating an example semiconductor device having N-tier wafer-on-wafer stacked circuit dies and redistribution layers in a silicon carrier that provide lateral communication between two or more circuit dies.

FIG. 9 is a block diagram illustrating an example semiconductor device having redistribution layers in a silicon carrier that provide lateral communication between channels of a circuit die.

FIG. 10 is a block diagram illustrating an example semiconductor device having N-tier stacked circuit dies and redistribution layers in a silicon carrier that provide lateral communication between channels of a circuit die.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for stack construction of a semiconductor device having redistribution layers in a silicon carrier. 3D stacked technology provides advantages of enabling heterogeneous integration of chiplets with fine vertical stacking pitches and increased performance compared to other technologies that enable heterogenous integration. Silicon bridge technology can provide lateral communication between dies but is not applicable in 3D architectures where top and bottom die sizes are similar. Additionally, silicon bridge integration has limited integration as it is governed by silicon bridge aspect ratio and size considerations. Also, silicon bridge routing is further limited to peripheral routing to the dies connected by the silicon bridge.

The disclosed systems and methods include redistribution layers (RDLs) in a carrier (e.g., silicon or any other material such as glass) in 3D stacked technology (e.g., chip-on-wafer (CoW) circuit dies, wafer-on-wafer (WoW) circuit dies, chip-on-reconstituted-wafer (CoRW) circuit dies, and/or N-tier stacked circuit dies). The disclosed 3D-stacked product process flow can enable lateral communication between dice without the need for a bridging layer (e.g., an interposer or a bridge die). Additional benefits include high throughput resulting from wafer level bonding and ability to use a passive top carrier that can be fabricated at reduced cost and provide higher yield compared to cutting edge technology nodes while delivering more functionality from the top carrier. Further benefits include applicability to WoW N-tier stacking and the ability to take advantage of fine alignment of wafer level bonding. Moreover, the disclosed carrier and semiconductor device is holistic to die sizes, whereas a top tier bridge die can only be used when top and bottom dies have different sizes.

In one example, a semiconductor device includes a plurality of stacked circuit dies, a carrier attached to the plurality of stacked circuit dies, and a plurality of redistribution layers in the carrier that provide lateral communication for one or more circuit dies of the plurality of stacked circuit dies.

Another example can be the previously described example semiconductor device, wherein the plurality of redistribution layers in the carrier provides lateral communication between two or more circuit dies of the plurality of stacked circuit dies.

Another example can be the semiconductor device of any of the previously described example semiconductor devices, wherein the plurality of redistribution layers in the carrier provides lateral communication between two or more channels of a circuit die of the plurality of stacked circuit dies.

Another example can be the semiconductor device of any of the previously described example semiconductor devices, wherein the carrier comprises a passive carrier.

Another example can be the semiconductor device of any of the previously described example semiconductor devices, wherein the carrier is attached to the plurality of stacked circuit dies by hybrid bonding.

Another example can be the semiconductor device of any of the previously described example semiconductor devices, wherein the plurality of stacked circuit dies includes layers of circuit dies all having a same size, and the semiconductor device has no bridge dies attached between the carrier and the plurality of stacked circuit dies.

Another example can be the semiconductor device of any of the previously described example semiconductor devices, wherein the plurality of stacked circuit dies includes a plurality of wafer-on-wafer stacked circuit dies.

Another example can be the semiconductor device of any of the previously described example semiconductor devices, wherein the plurality of wafer-on-wafer stacked circuit dies includes a plurality of N-tier wafer-on-wafer stacked circuit dies.

Another example can be the semiconductor device of any of the previously described example semiconductor devices, wherein the plurality of stacked circuit dies includes a plurality of chip-on-wafer stacked circuit dies.

Another example can be the semiconductor device of any of the previously described example semiconductor devices, wherein the plurality of chip-on-wafer stacked circuit dies includes a plurality of N-tier chip-on-wafer stacked circuit dies.

Another example can be the semiconductor device of any of the previously described example semiconductor devices, wherein the plurality of stacked circuit dies includes a plurality of chip-on-reconstituted-wafer stacked circuit dies.

In one example, a carrier includes a first redistribution layer in the carrier, and a second redistribution layer in the carrier, wherein the first redistribution layer and the second redistribution layer are configured, upon attachment of the carrier to a plurality of stacked circuit dies, to provide lateral communication for one or more circuit dies of the plurality of stacked circuit dies.

Another example can be the previously described example carrier, wherein the carrier comprises a passive carrier.

Another example can be any of the previously described example carriers, wherein the carrier is attachable to the plurality of stacked circuit dies by hybrid bonding.

Another example can be any of the previously described example carriers, wherein the carrier is directly attachable to the plurality of stacked circuit dies.

Another example can be any of the previously described example carriers, wherein the first redistribution layer and the second redistribution layer are configured to provide lateral communication between two or more circuit dies of the plurality of stacked circuit dies without any bridge dies being attached between the carrier and the plurality of stacked circuit dies.

Another example can be any of the previously described example carriers, wherein the first redistribution layer and the second redistribution layer are configured to provide lateral communication between two or more channels of a circuit die of the plurality of stacked circuit dies.

In one example, a method includes attaching a plurality of stacked circuit dies to a first carrier, attaching a second carrier to the plurality of stacked circuit dies, wherein the second carrier includes one or more redistribution layers therein that provide lateral communication for one or more circuit dies of the plurality of stacked circuit dies, and removing the first carrier.

Another example can be the previously described example method, wherein attaching the plurality of stacked circuit dies to the first carrier includes attaching a first circuit die to the first carrier, revealing through-silicon vias formed in the first circuit die by thinning the first circuit die, attaching a second circuit die to the first circuit die, and revealing through-silicon vias formed in the second circuit die by thinning the second circuit die.

Another example can be any of the previously described example methods, wherein at least one of the one or more redistribution layers in the second carrier provides lateral communication between two or more circuit dies of the plurality of stacked circuit dies, or the one or more redistribution layers in the second carrier provides lateral communication between two or more channels of a circuit die of the plurality of stacked circuit dies.

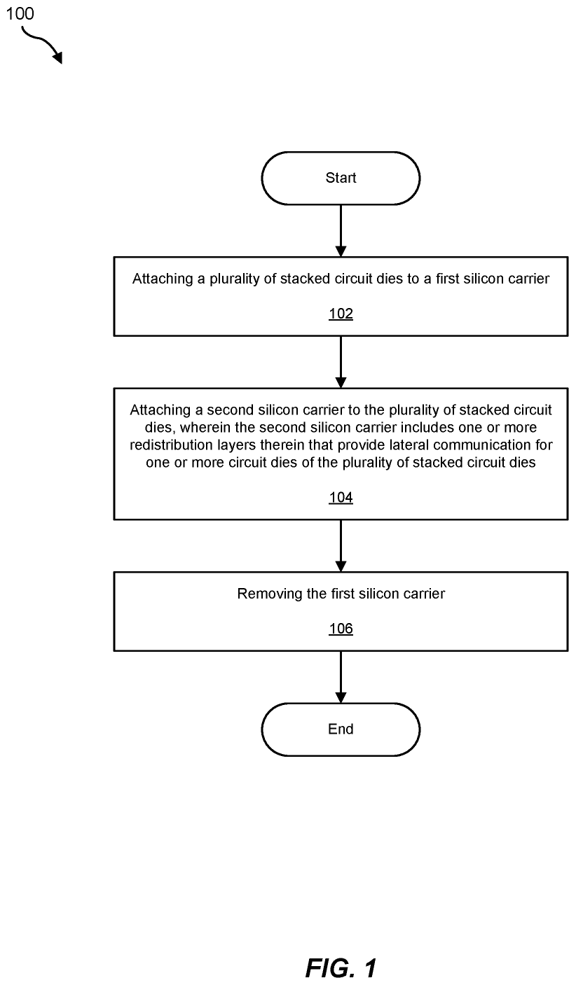

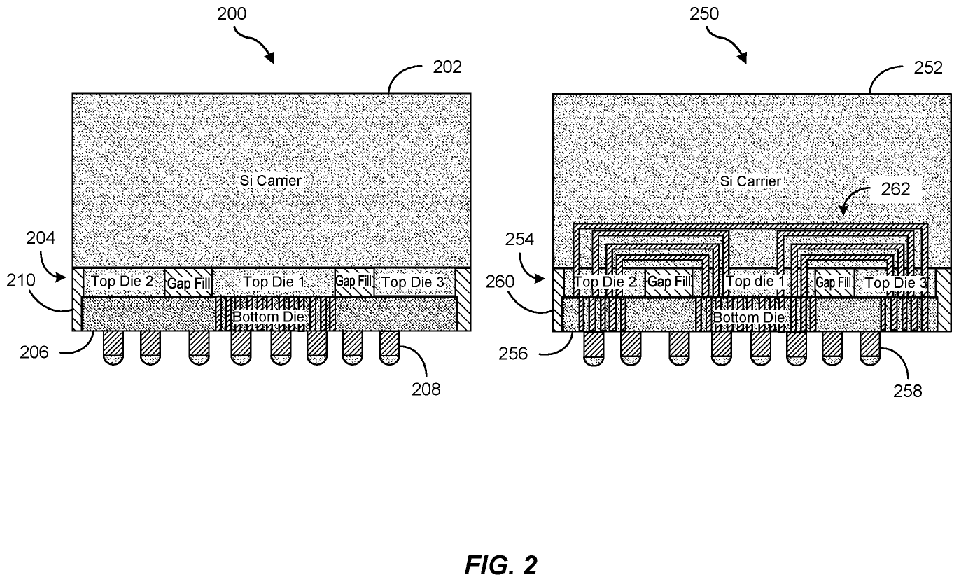

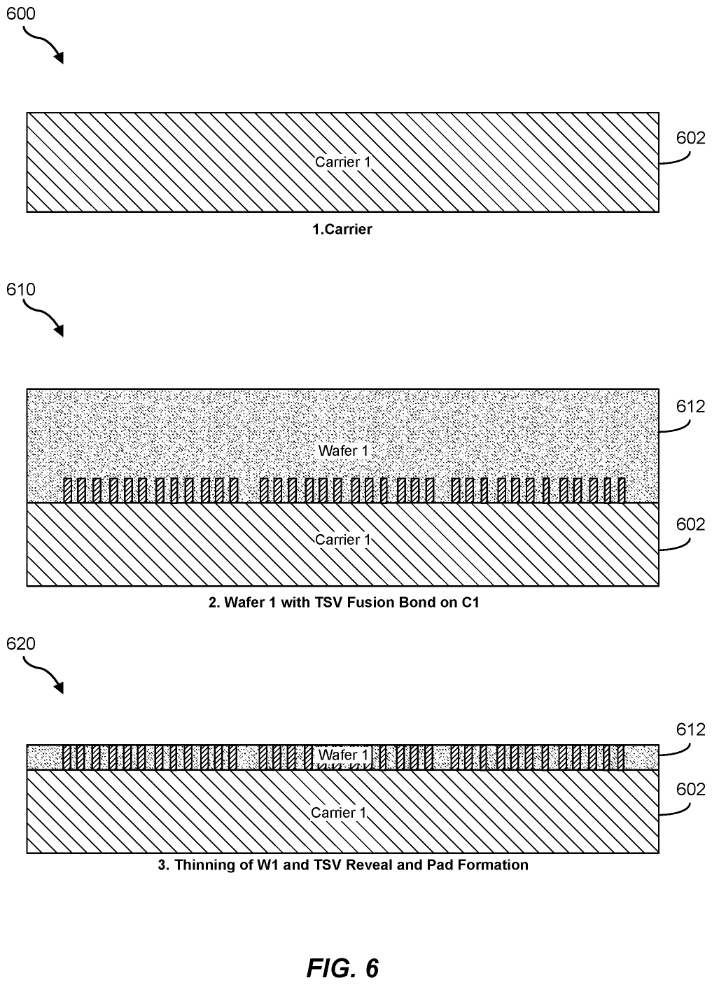

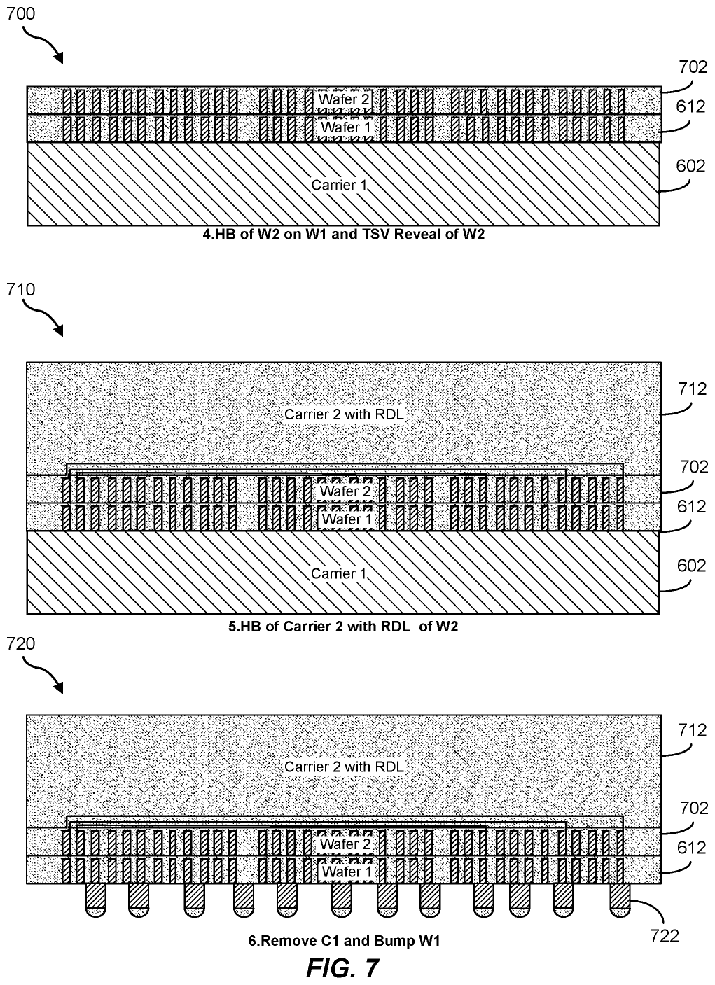

The following will provide, with reference to FIG. 1, detailed descriptions of example methods for stack construction of a semiconductor device having redistribution layers in a silicon carrier. In addition, detailed descriptions of example semiconductor devices having redistribution layers in a silicon carrier will be provided in connection with FIGS. 2-5. Also, detailed descriptions of exampled techniques for stack construction of a semiconductor device having redistribution layers in a silicon carrier will be provided in connection with FIGS. 6 and 7.

FIG. 1 is a flow diagram of an example method 100 for stack construction of a semiconductor device having redistribution layers in a silicon carrier. The steps shown in FIG. 1 can be performed by any suitable manufacturing process, computer-executable code, and/or computing system. In one example, each of the steps shown in FIG. 1 can represent an algorithm whose structure includes and/or is represented by multiple sub-steps, examples of which will be provided in greater detail below.

As illustrated in FIG. 1, at step 102, stack construction of a semiconductor device having redistribution layers in a silicon carrier can include attaching circuit dies to a carrier. For example, the stack construction of the semiconductor device having redistribution layers in the silicon carrier can include attaching a plurality of stacked circuit dies to a first carrier.

The term “circuit die,” as used herein, can generally refer to a small block of semiconducting material on which a given functional circuit is fabricated. For example, and without limitation, integrated circuits can be produced in large batches on a single wafer of electronic-grade silicon (EGS) or other semiconductor through processes such as photolithography.

The term “carrier,” as used herein, can generally refer to a layer of material that ensures integrity and cleanliness of a wafer in a semiconductor device. For example, and without limitation, carriers used in stacked wafers and/or circuit dies can be made of silicon or any other material, such as glass. A carrier substrate can be used at a bottom of the stack for depositing stacked wafers, a top carrier can be bonded to the top tier circuit dies, and the carrier substrate can be removed. Thus, one or more carriers can be temporarily and/or permanently attached to one or more wafers during manufacture of a semiconductor device. Top carriers can provide protection to semiconductor wafers in front-end and back-end fabrication. In this context, the term “carrier” can refer to a top carrier (e.g., silicon or glass) thermally bonded to the top tier of stacked circuit dies.

The term “redistribution layer,” as used herein, can generally refer to communication pathways. For example, and without limitation, redistribution layers (RDLs) can be copper metal interconnects that electrically connect one part of a semiconductor package to another. Alternatively or additionally, RDLs can be an extra metal layer on an integrated circuit that makes its input/output (IO) pads available in other locations of the chip, for better access to the pads where necessary. When an integrated circuit is manufactured, it usually has a set of IO pads that are wire bonded to pins of a chip package. A redistribution layer can thus be an extra layer of wiring on the chip that enables bond out from different locations on the chip, making chip-to-chip bonding simpler. Another example of the use for RDLs is for spreading contact points around a die so that solder balls can be applied, and thermal stress of mounting can be spread.

The systems described herein can perform step 102 in a variety of ways. In one example, attaching the plurality of stacked circuit dies to the first carrier can include attaching a first circuit die to the first carrier, revealing through-silicon vias formed in the first circuit die by thinning the first circuit die, attaching a second circuit die to the first circuit die, and revealing through-silicon vias formed in the second circuit die by thinning the second circuit die. In some examples, attaching the plurality of stacked circuit dies to the first carrier can include attaching the first circuit die to the first carrier by through-silicon via fusion bonding. In some examples, attaching the plurality of stacked circuit dies to the first carrier can include attaching the second circuit die to the first circuit die by hybrid bonding. In some examples, attaching the plurality of stacked circuit dies to the first carrier can include providing the first carrier. In some examples, the first carrier can comprise a silicon carrier.

At step 104, the stack construction of the semiconductor device having redistribution layers in the silicon carrier can include attaching a carrier to one or more circuit dies. For example, the stack construction of the semiconductor device having redistribution layers in the silicon carrier can include attaching a second carrier to the plurality of stacked circuit dies, wherein the second carrier includes one or more redistribution layers therein that provide lateral communication for one or more circuit dies of the plurality of stacked circuit dies.

The systems described herein can perform step 104 in a variety of ways. In one example, the one or more redistribution layers in the second carrier can provide lateral communication between two or more circuit dies of the plurality of stacked circuit dies. Alternatively or additionally, the one or more redistribution layers in the second carrier can provide lateral communication between two or more channels of a circuit die of the plurality of stacked circuit dies. In some examples, attaching the second carrier to the plurality of stacked circuit dies can include attaching the second carrier to the plurality of stacked circuit dies by hybrid bonding. In some examples, attaching the second carrier to the plurality of stacked circuit dies can include providing the second carrier. In some examples, the second carrier can comprise a silicon carrier. In some examples, the second carrier can comprise a passive carrier. In some examples, the plurality of stacked circuit dies can include layers of circuit dies all having a same size and attaching the second carrier to the plurality of stacked circuit dies can include attaching the second carrier to the plurality of stacked circuit dies with no bridge dies attached between the second carrier and the plurality of stacked circuit dies. In other examples, the plurality of stacked circuit dies can include two or more layers of circuit dies of different sizes and attaching the second carrier to the plurality of stacked circuit dies can include attaching the second carrier to the plurality of stacked circuit dies with no bridge dies attached between the second carrier and the plurality of stacked circuit dies. In one or more examples, the plurality of stacked circuit dies can include a plurality of wafer-on-wafer stacked circuit dies, a plurality of chip-on-wafer stacked circuit dies, a plurality of chip-on-reconstituted-wafer circuit dies, and/or a plurality of N-tier stacked circuit dies.

At step 106, the stack construction of the semiconductor device having redistribution layers in the silicon carrier can include removing a carrier. For example, the stack construction of the semiconductor device having redistribution layers in the silicon carrier can include removing the first carrier.

The systems described herein can perform step 106 in a variety of ways. In one example, removing the first carrier can be accompanied by attaching one or more bumps to the first circuit die. In some of these examples, attaching one or more bumps to the first circuit die can include attaching the one or more bumps to the plurality of circuit dies on a side opposite to a side on which the second circuit die is attached.

The term “bumps,” as used herein, can generally refer to connective materials that physically and communicatively bond a semiconductor device to a substrate and/or chip. For example, and without limitation, bumps can refer to solder bumps that are small spheres of solder bonded to contact areas or pads of a semiconductor device. In some examples, the bumps can be used for face-down bonding.

Referring to FIG. 2, example semiconductor devices can be of chip-on-reconstituted-wafer (CoRW) stack construction. For example, semiconductor device 200 can include a silicon carrier 202 attached to a top layer of circuit dies 204. Additionally, semiconductor device 200 can include a bottom layer circuit die 206 attached to the top layer of circuit dies 204. Also, semiconductor device 200 can include a plurality of bumps 208 attached to the bottom layer circuit die 206. Gap fill material 210 can be provided in and/or around the layers of dies as shown. Without any bridge dies or an interposer, semiconductor device 200 can lack lateral communication between circuit dies 204 and/or 206.

Like semiconductor device 200, semiconductor device 250 can include a silicon carrier 252 attached to a top layer of circuit dies 254 that is attached to a bottom layer circuit die 256. Also like semiconductor device 200, semiconductor device 250 can include a plurality of bumps 258 attached to the bottom layer circuit die 256 and have gap fill material 260 provided in and/or around the layers of dies as shown. Without any bridge dies or an interposer, semiconductor device 200 can lack lateral communication between circuit dies 204 and/or 206. However, unlike semiconductor device 200, semiconductor device 250 can include redistribution layers 262 that provide lateral communication between circuit dies 254 and/or 256. Redistribution layers 262 can be formed of any suitable communication medium (e.g., metal, doped semiconductor material, wave guides, through-silicon vias, etc.).

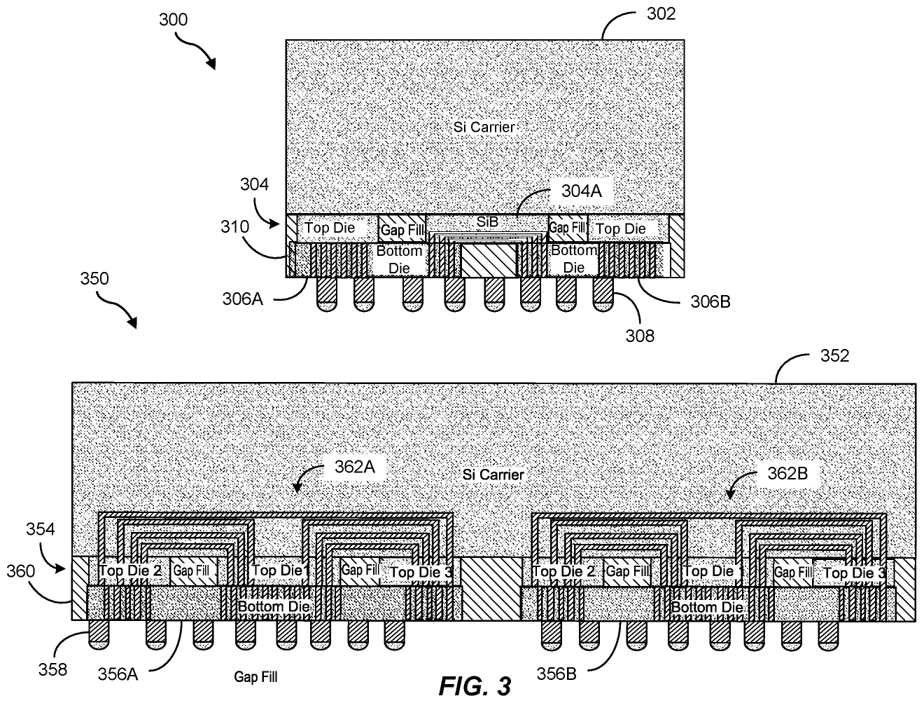

Referring to FIG. 3, example semiconductor devices also can be of CoRW stack construction. For example, semiconductor device 300 can include a silicon carrier 302 attached to a top layer of circuit dies 304 that include a silicon bridge (SiB) die 304A. Additionally, semiconductor device 300 can include bottom layer circuit dies 306A and 306B attached to the top layer of circuit dies 304. Also, semiconductor device 300 can include a plurality of bumps 308 attached to the bottom layer circuit dies 306A and 306B. Gap fill material 310 can be provided in and/or around the layers of dies as shown. Without an interposer, semiconductor device 300 can use bridge die 304A to provide lateral communication between top layer circuit dies 304 and/or bottom layer circuit dies 306A and 306B.

Like semiconductor device 300, semiconductor device 350 can include a silicon carrier 352 attached to a top layer of circuit dies 354 that is attached to bottom layer circuit dies 356A and 356B. Also like semiconductor device 300, semiconductor device 350 can include a plurality of bumps 358 attached to the bottom layer circuit dies 356A and 356B and have gap fill material 360 provided in and/or around the layers of dies as shown. However, unlike semiconductor device 300, semiconductor device 350 can include redistribution layers 362A and 362B that provide lateral communication between the top layer of circuit dies 354 and the bottom layer of circuit dies 356A and 356B. For example, semiconductor device 350 can have a top layer of circuit dies 354 that includes larger and/or additional circuit dies. Redistribution layers 362A and 362B can be formed of any suitable communication medium (e.g., metal, doped semiconductor material, wave guides, through-silicon vias, etc.). Use of silicon carrier 352 that includes redistribution layers 362A and 362B providing lateral communication between top layer circuit dies 354 and/or bottom layer circuit dies 356A and 356B can provide the lateral communication without the need for any bridge dies or an interposer.

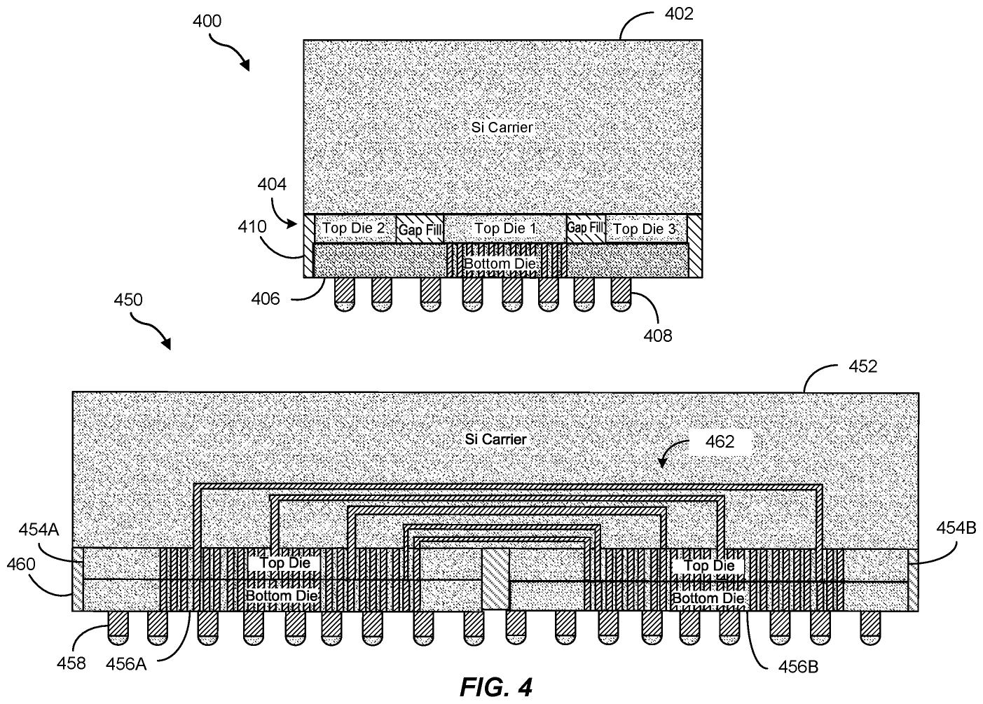

Referring to FIG. 4, example semiconductor devices can be of wafer-on-wafer (WoW) stack construction. For example, semiconductor device 400 can include a silicon carrier 402 attached to a top layer of circuit dies 404. Additionally, semiconductor device 400 can include a bottom layer circuit die 406 attached to the top layer of circuit dies 404. Also, semiconductor device 400 can include a plurality of bumps 408 attached to the bottom layer circuit die 406. Gap fill material 410 can be provided in and/or around the layers of dies as shown. Without any bridge dies or an interposer, semiconductor device 400 can lack lateral communication between circuit dies 404 and/or 406.

Like semiconductor device 400, semiconductor device 450 can include a silicon carrier 452 attached to a top layer of circuit dies 454A and 454B that is attached to bottom layer circuit dies 456A and 456B. Also like semiconductor device 400, semiconductor device 450 can include a plurality of bumps 458 attached to the bottom layer circuit dies 456A and 456B and have gap fill material 460 provided in and/or around the layers of dies as shown. However, unlike semiconductor device 400, semiconductor device 450 can include redistribution layers 462 that provide lateral communication between the top layer of circuit dies 454A and 454B and the bottom layer of circuit dies 456A and 456B. Redistribution layers 462 can be formed of any suitable communication medium (e.g., metal, doped semiconductor material, wave guides, through-silicon vias, etc.). Use of silicon carrier 452 that includes redistribution layers 462 can provide lateral communication without the need for any bridge dies or an interposer. In addition to reducing costs, this capability allows circuit dies of the semiconductor device 450 to be of a same size. However, silicon carrier 452 that includes redistribution layers 462 can alternatively be used with circuit dies of different sizes.

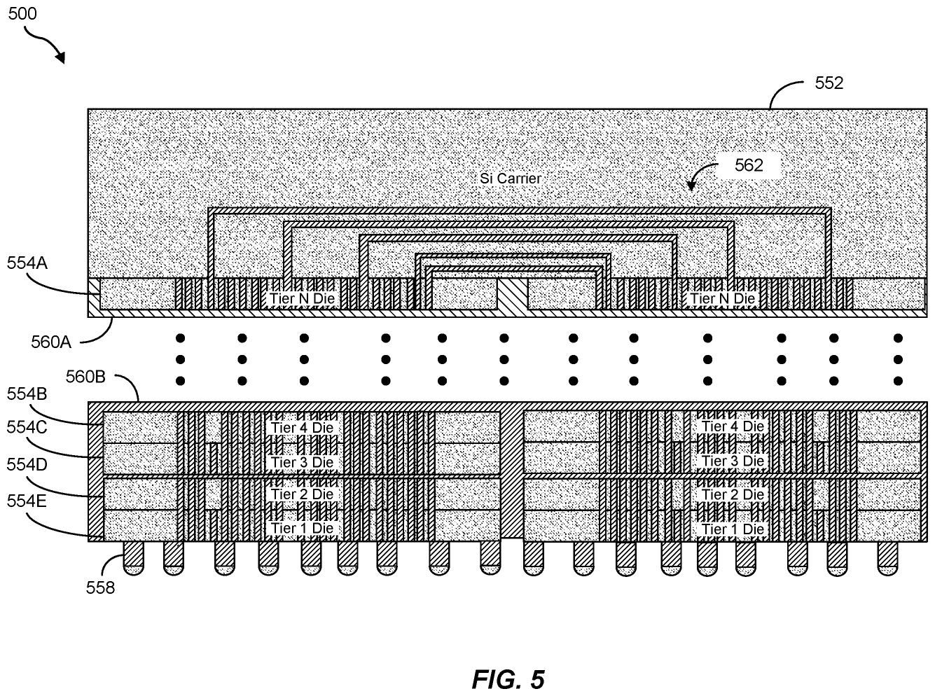

Referring to FIG. 5, a semiconductor device 500 of chip-on-wafer (CoW) (e.g., chip-on-reconstituted-wafer (CoRW) stack construction can includer N-tier chip-on-wafer stacked circuit dies, where N is an integer greater than two. For example, semiconductor device 500 can include a silicon carrier 552 attached to a plurality of chip-on-wafer stacked circuit dies 554A-554E. Additionally, semiconductor device 500 can include a plurality of bumps 558 attached to the plurality of chip-on-wafer stacked circuit dies 554A-554E. Gap fill material 560A and 560B can be provided in and/or around the layers of dies 554A-554E as shown. Semiconductor device 500 can include redistribution layers 562 that provide lateral communication between any or all of the N-tier chip-on-wafer stacked circuit dies 554A-554E. Redistribution layers 562 can be formed of any suitable communication medium (e.g., metal, doped semiconductor material, wave guides, through-silicon vias, etc.). Use of silicon carrier 552 that includes redistribution layers 562 can provide lateral communication without the need for any bridge dies or an interposer. In addition to reducing costs, this capability allows circuit dies of the semiconductor device 500 to be of a same size. However, silicon carrier 552 that includes redistribution layers 562 can alternatively be used with circuit dies of different sizes.

Referring to FIG. 6, initial stages of stacked construction of a semiconductor device having redistribution layers in a silicon carrier are shown. At 600, a first carrier 602 (e.g., silicon carrier) can be provided. At 610, a first wafer 612 can be attached to the first carrier 602 by TSV fusion bonding. At 620, the first wafer 612 can be thinned during pad formation to reveal the TSVs in the first wafer 612. First wafer 612 can include one or multiple circuit dies.

Referring to FIG. 7, terminal stages of stacked construction of a semiconductor device having redistribution layers in a silicon carrier are shown. At 700, a second wafer 702 can be attached to the first wafer 612 by hybrid bonding and thinned during pad formation to reveal TSVs in the second wafer 702. Second wafer 702 can include one or multiple circuit dies. At 710, a second carrier 712 (e.g., silicon) having redistribution layers can be attached to the second wafer 702 by hybrid bonding. At 720, the first carrier 602 can be removed, and bumps 722 can be added to the first wafer 612 on a side opposite the second carrier 712. One or more redistribution layers in the second carrier can provide lateral communication between two or more circuit dies of the plurality of stacked circuit dies and/or between two or more channels of a circuit die of the plurality of stacked circuit dies.

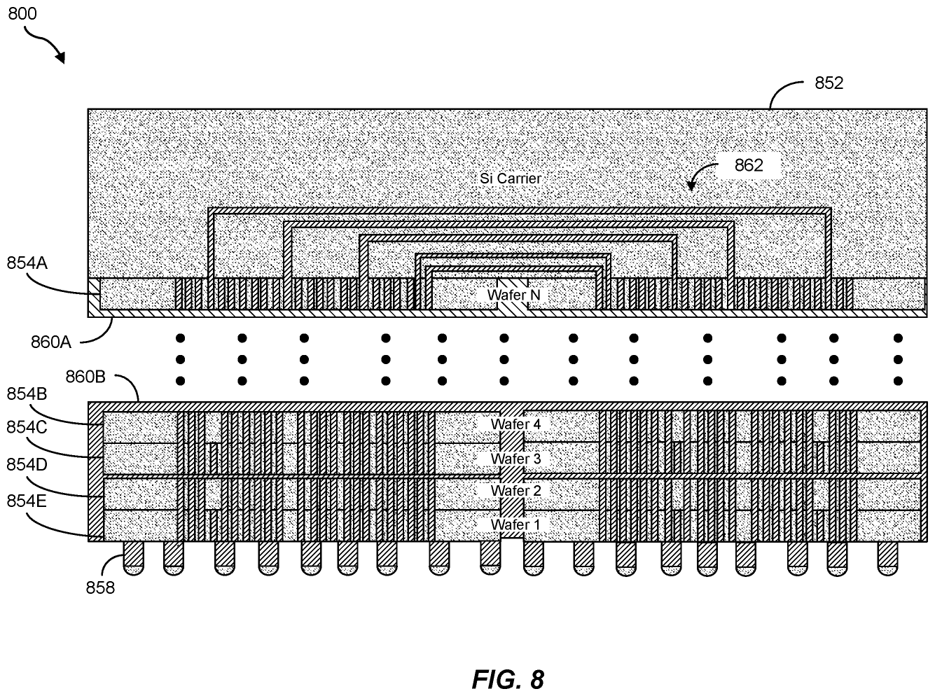

Referring to FIG. 8, a semiconductor device 800 of wafer-on-wafer (WoW) stack construction can includer N-tier wafer-on-wafer stacked circuit dies, where N is an integer greater than two. For example, semiconductor device 800 can include a silicon carrier 852 attached to a plurality of wafer-on-wafer stacked circuit dies 854A-854E. Additionally, semiconductor device 800 can include a plurality of bumps 858 attached to the plurality of stacked circuit dies 854A and 854E. Gap fill material 860A and 860B can be provided in and/or around the layers of dies 854A-854E as shown. Semiconductor device 800 can include redistribution layers 862 that provide lateral communication between any or all of the N-tier wafer-on-wafer stacked circuit dies 854A-854E. Redistribution layers 862 can be formed of any suitable communication medium (e.g., metal, doped semiconductor material, wave guides, through-silicon vias, etc.). Use of silicon carrier 852 that includes redistribution layers 862 can provide lateral communication without the need for any bridge dies or an interposer. In addition to reducing costs, this capability allows circuit dies of the semiconductor device 800 to be of a same size. However, silicon carrier 852 that includes redistribution layers 862 can alternatively be used with circuit dies of different sizes.

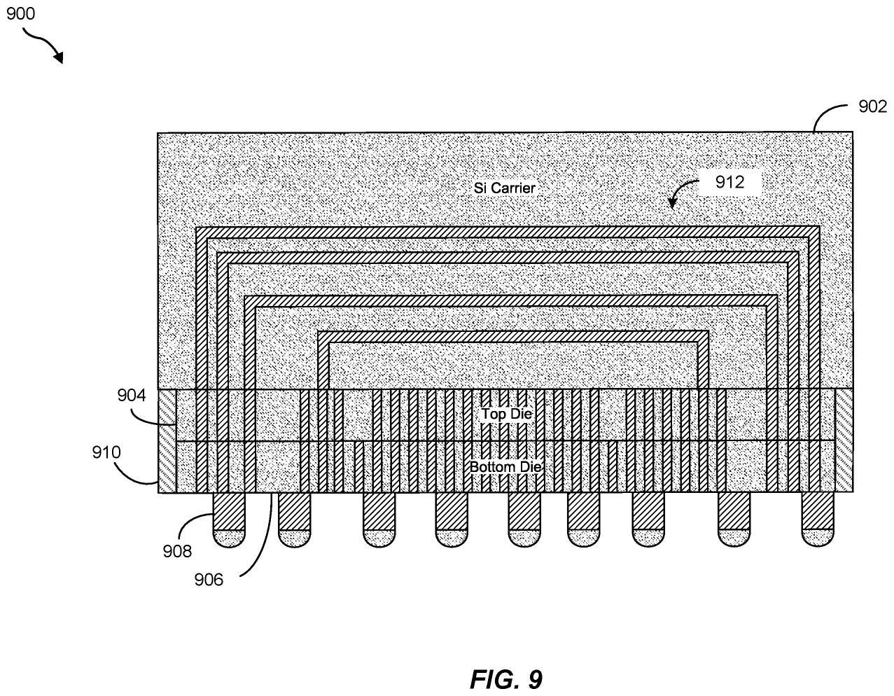

Referring to FIG. 9, an example semiconductor device 900 can include a silicon carrier 902 attached to a top layer circuit die 904. Additionally, semiconductor device 900 can include a bottom layer circuit die 906 attached to the top layer circuit die 904. Also, semiconductor device 900 can include a plurality of bumps 908 attached to the bottom layer circuit die 906. Gap fill material 910 can be provided in and/or around the layers of dies as shown.

Silicon carrier 902 can include redistribution layers 912 that provide lateral communication between channels of the top layer of circuit die 904. These channels can be any suitable communication channels, such as electrical or optical waveguides. For example, the channels can be through silicon vias. Redistribution layers 912 can be formed of any suitable communication medium (e.g., metal, doped semiconductor material, wave guides, through-silicon vias, etc.). Use of silicon carrier 902 that includes redistribution layers 912 can provide lateral communication between channels of a particular circuit die without the need for any bridge dies or an interposer. In addition to reducing costs, this capability allows circuit dies of the semiconductor device 900 to be of a same size. However, silicon carrier 902 that includes redistribution layers 912 can alternatively be used with circuit dies of different sizes. Moreover, the disclosed carrier 902 can provide a top layer of multiple circuit dies with lateral communication both between dies and between channels of a particular one of the multiple circuit dies. Carrier 902 can be used with any type of 3D stacked technology (e.g., chip-on-wafer (CoW) circuit dies, wafer-on-wafer (WoW) circuit dies, chip-on-reconstituted-wafer (CoRW) circuit dies, and/or N-tier stacked circuit dies).

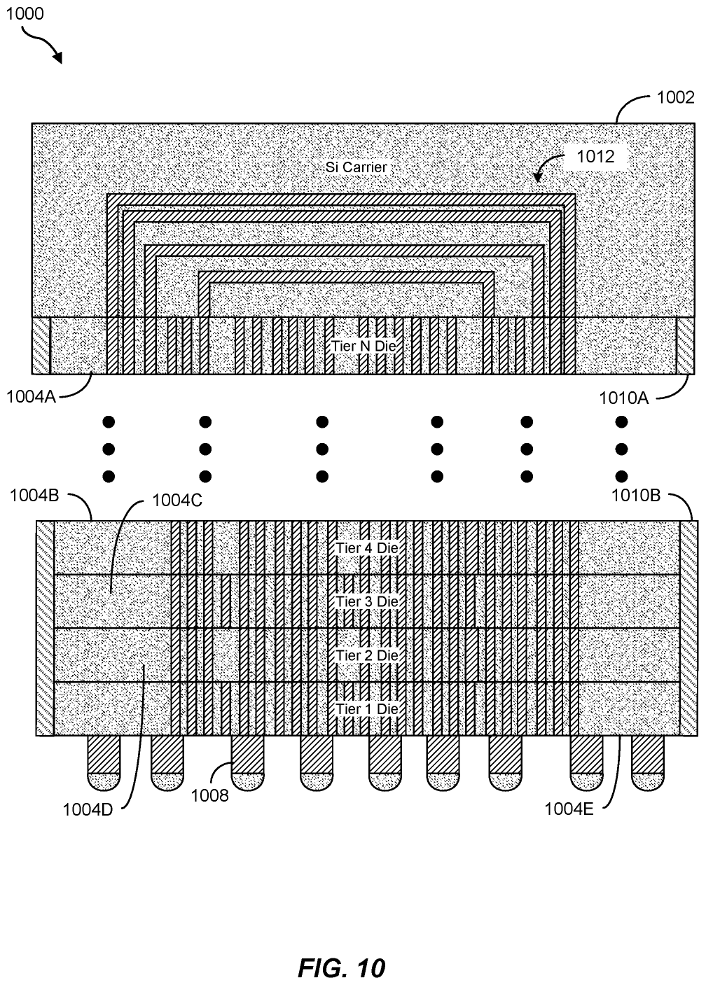

Referring to FIG. 10, a semiconductor device 1000 can includer N-tier stacked circuit dies, where N is an integer greater than two. For example, semiconductor device 1000 can include a silicon carrier 1002 attached to a plurality of stacked circuit dies 1004A-1004E. Additionally, semiconductor device 1000 can include a plurality of bumps 1008 attached to the bottom circuit die 1004E. Gap fill material 1010A and 1010B can be provided in and/or around the layers of dies 1004A-1004E as shown. Semiconductor device 1000 can include redistribution layers 1012 that provide lateral communication between channels (e.g., communication channels, electrical waveguides, optical waveguides, through silicon vias, etc.) of the top circuit die 1004A. Redistribution layers 1012 can be formed of any suitable communication medium (e.g., metal, doped semiconductor material, wave guides, through-silicon vias, etc.). Use of silicon carrier 1002 that includes redistribution layers 1012 can provide lateral communication without the need for any bridge dies or an interposer. In addition to reducing costs, this capability allows circuit dies of the semiconductor device 1000 to be of a same size. However, silicon carrier 1002 that includes redistribution layers 1012 can alternatively be used with circuit dies of different sizes. Moreover, the disclosed carrier 1002 can provide a top layer of multiple circuit dies with lateral communication both between dies and between channels of a particular one of the multiple circuit dies. Carrier 1002 can be used with any type of 3D stacked technology (e.g., chip-on-wafer (CoW) circuit dies, wafer-on-wafer (WoW) circuit dies, chip-on-reconstituted-wafer (CoRW) circuit dies, and/or N-tier stacked circuit dies).

As set forth above, the disclosed systems and methods include redistribution layers (RDLs) in a carrier (e.g., silicon or any other material such as glass) in 3D stacked technology (e.g., chip-on-wafer (CoW) circuit dies, wafer-on-wafer (WoW) circuit dies, chip-on-reconstituted-wafer (CoRW) circuit dies, and/or N-tier stacked circuit dies). The disclosed 3D-stacked product process flow can enable lateral communication between circuit dies and/or channels of a particular circuit die without the need for a bridging layer (e.g., an interposer or a bridge die). Additional benefits include high throughput resulting from wafer level bonding and ability to use a passive top carrier that can be fabricated at reduced cost and provide higher yield compared to cutting edge technology nodes while delivering more functionality from the top carrier. Further benefits include applicability to WOW N-tier stacking and the ability to take advantage of fine alignment of wafer level bonding. Moreover, the disclosed carrier and semiconductor device is holistic to die sizes.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device, comprising:
a plurality of stacked circuit dies;
a carrier attached to the plurality of stacked circuit dies; and
a plurality of redistribution layers in the carrier that provide lateral communication for one or more circuit dies of the plurality of stacked circuit dies.

2. The semiconductor device of claim 1, wherein the plurality of redistribution layers in the carrier provides lateral communication between two or more circuit dies of the plurality of stacked circuit dies.

3. The semiconductor device of claim 1, wherein the plurality of redistribution layers in the carrier provides lateral communication between two or more channels of a circuit die of the plurality of stacked circuit dies.

4. The semiconductor device of claim 1, wherein the carrier comprises a passive carrier.

5. The semiconductor device of claim 1, wherein the carrier is attached to the plurality of stacked circuit dies by hybrid bonding.

6. The semiconductor device of claim 1, wherein:
the plurality of stacked circuit dies includes layers of circuit dies all having a same size; and
the semiconductor device has no bridge dies attached between the carrier and the plurality of stacked circuit dies.

7. The semiconductor device of claim 1, wherein the plurality of stacked circuit dies includes a plurality of wafer-on-wafer stacked circuit dies.

8. The semiconductor device of claim 7, wherein the plurality of wafer-on-wafer stacked circuit dies includes a plurality of N-tier wafer-on-wafer stacked circuit dies.

9. The semiconductor device of claim 1, wherein the plurality of stacked circuit dies includes a plurality of chip-on-wafer stacked circuit dies.

10. The semiconductor device of claim 9, wherein the plurality of chip-on-wafer stacked circuit dies includes a plurality of N-tier chip-on-wafer stacked circuit dies.

11. The semiconductor device of claim 9, wherein the plurality of chip-on-wafer stacked circuit dies includes a plurality of chip-on-reconstituted-wafer stacked circuit dies.

12. A carrier comprising:
a first redistribution layer in the carrier; and
a second redistribution layer in the carrier,
wherein the first redistribution layer and the second redistribution layer are configured, upon attachment of the carrier to a plurality of stacked circuit dies, to provide lateral communication for one or more circuit dies of the plurality of stacked circuit dies.

13. The carrier of claim 12, wherein the carrier comprises a passive carrier.

14. The carrier of claim 12, wherein the carrier is attachable to the plurality of stacked circuit dies by hybrid bonding.

15. The carrier of claim 12, wherein the carrier is directly attachable to the plurality of stacked circuit dies.

16. The carrier of claim 15, wherein the first redistribution layer and the second redistribution layer are configured to provide lateral communication between two or more circuit dies of the plurality of stacked circuit dies without any bridge dies being attached between the carrier and the plurality of stacked circuit dies.

17. The carrier of claim 15, wherein the first redistribution layer and the second redistribution layer are configured to provide lateral communication between two or more channels of a circuit die of the plurality of stacked circuit dies.

18. A method comprising:
attaching a plurality of stacked circuit dies to a first carrier;
attaching a second carrier to the plurality of stacked circuit dies, wherein the second carrier includes one or more redistribution layers therein that provide lateral communication for one or more circuit dies of the plurality of stacked circuit dies; and
removing the first carrier.

19. The method of claim 18, wherein attaching the plurality of stacked circuit dies to the first carrier includes:
attaching a first circuit die to the first carrier;
revealing through-silicon vias formed in the first circuit die by thinning the first circuit die;
attaching a second circuit die to the first circuit die; and
revealing through-silicon vias formed in the second circuit die by thinning the second circuit die.

20. The method of claim 18, wherein at least one of:
the one or more redistribution layers in the second carrier provides lateral communication between two or more circuit dies of the plurality of stacked circuit dies; or
the one or more redistribution layers in the second carrier provides lateral communication between two or more channels of a circuit die of the plurality of stacked circuit dies.
